(19) United States
(12) Patent Application Publication
(10) Pub. No.: US 2014/0115360 A1
(43) Pub. Date: Apr. 24, 2014

(54) Method for Reducing Dynamic Power Consumption and Electronic Device

(71) Applicant: Huawei Technologies Co., Ltd., Shenzhen (CN)

(72) Inventors: Yonghui Zhou, Shanghai (CN); Jianfeng Yu, Shanghai (CN)

(73) Assignee: Huawei Technologies Co., Ltd., Shenzhen (CN)

(21) Appl. No.: 14/145,275

(22) Filed: Dec. 31, 2013

Related U.S. Application Data
(63) Continuation of application No. PCT/CN2011/081245, filed on Oct. 25, 2011.

(51) Int. Cl. G06F 1/32; G06F 1/26; H03L 5/02

(52) U.S. Cl. CPC G06F 1/325; H03L 5/02; G06F 1/266
USPC 713/320; 327/142

(57) ABSTRACT

The present invention relates to a method for reducing dynamic power consumption and an electronic device. The method includes: receiving a bus signal; when information about access to the slave device exists in the bus signal, inputting a clock signal into the slave device and detecting a status signal sent by the slave device; and stopping inputting the clock signal into the slave device when the status signal of the slave device indicates that the slave device is in an idle state. A working clock of a device module, such as a slave device, in a chip is controlled by using a status signal of the slave device and a bus signal, which prevents unnecessary circuit turnover from occurring to the device module in the chip in a non-working state, thereby achieving a purpose of reducing dynamic power consumption of the device module in the chip.

### CROSS-REFERENCE TO RELATED APPLICATIONS

This application is a continuation of International Application No. PCT/CN2011/081245, filed on Oct. 25, 2011, which is hereby incorporated by reference in its entirety.

### TECHNICAL FIELD

The present invention relates to an energy-saving technology of a device module in a chip, and in particular to a method for reducing dynamic power consumption and an electronic device.

### BACKGROUND

With the application and development of wireless chips, reducing power consumption of chips also becomes an increasingly urgent requirement.

Power consumption of a chip includes static power consumption and dynamic power consumption.

For example, bus architecture based on Advanced Microcontroller Bus Architecture (AMBA) 2.0 AMBA High-performance Bus (AHB) includes three parts, that is, a bus (AHB Local Bus), a master device module, and a slave device module. The master device module and the slave device module may be devices such as Internet Protocol (IP) cores, chips, or functional modules, which are both connected to an AMBA bus. Whether dynamic power consumption of the master device module and the slave device module can be saved depends on whether internal logic circuits of these devices can be stopped from working when the devices do not work.

According to a method for reducing power consumption of master and slave devices, a clock gating module is added in system control design during system design to control a working reference clock of a connected device in a system; alternatively, there is a function for saving power consumption inside a device in a system, such as clock gating. In a working process of a system, software is used to detect and determine whether a corresponding device can enter a power consumption saving state. If the corresponding device can enter a power consumption saving state at a certain moment, the software is used to configure a power consumption saving register corresponding to the corresponding device, so as to enable the corresponding device to enter a dynamic power consumption saving state.

According to this method for reducing dynamic power consumption, software is used to implement detection and configuration for entering a power consumption saving state, which brings an additional overhead to software running. Moreover, when the software is used to control the entering of the power consumption saving state, timeliness is poor and a power consumption saving effect is not good enough. In addition, the method restricts and depends on a device itself or system design, that is, the device itself must have a power consumption saving function. For some devices that do not have a power consumption saving function, the function can be implemented only by using a bus system to control the devices to turn off working clocks.

According to another method for reducing power consumption of master and slave devices, a gating unit is automatically inserted by using an integrated tool according to a logic function in a process of implementing design of a chip or a programmable device. During working of the chip or the programmable device, modules driven by a signal of the inserted gating unit are controlled by the gating unit to turn on or turn off a circuit, so as to achieve a purpose of reducing power consumption.

According to this method for reducing dynamic power consumption, a gating unit is automatically inserted by using an integrated tool according to a logic function. In an actual implementation process, only gating of a small part of a circuit in a chip or a programmable device can be optimized, but gating of a large logic circuit cannot be optimized. Therefore, an overall gating effect is not obvious, and gains of saving power consumption are also not obvious.

### SUMMARY

Embodiments of the present invention provide a method for reducing dynamic power consumption and an electronic device so as to reduce dynamic power consumption of a device module in a chip in a hardware manner and improve timeliness and an effect of saving dynamic power consumption.

An embodiment of the present invention provides a method for reducing dynamic power consumption, which is used to reduce dynamic power consumption of a slave device and includes: receiving a bus signal; when information about access to the slave device exists in the bus signal, inputting a clock signal into the slave device and detecting a status signal sent by the slave device; and stopping inputting the clock signal into the slave device when the status signal of the slave device indicates that the slave device is in an idle state.

An embodiment of the present invention further provides an electronic device, including a slave device, configured to receive and process, through a bus, access information sent by another device, where the electronic device further includes: a detecting module, configured to detect a status signal of the slave device and a bus signal; and a clock module, configured to input a clock signal into the slave device when the detecting module detects that information about access to the slave device exists in the bus signal, and stop inputting the clock signal into the slave device when the detecting module detects that the status signal of the slave device indicates that the slave device is in an idle state.

According to the method for reducing dynamic power consumption and the electronic device provided in the embodiments of the present invention, a working clock of a device module in a chip is controlled by detecting a status signal of a slave device and a bus signal, which prevents unnecessary circuit turnover from occurring to the slave device, that is, the device module in the chip, in a non-working state, thereby achieving a purpose of reducing dynamic power consumption of the device module in the chip. Moreover, a clock signal is input or stopped from being input into the slave device according to a result of detecting the status signal of the slave device and the bus signal, which prevents an additional load from being brought to software running due to detection and configuration implemented by using software for entering a power consumption saving state in the prior art, and solves a problem that poor timeliness and a poor power consumption saving effect are caused by using the software to control the entering of the power consumption saving state.

### BRIEF DESCRIPTION OF DRAWINGS

To describe the technical solutions in the embodiments of the present invention more clearly, the following briefly introduces the accompanying drawings required for describing the embodiments. Apparently, the accompanying drawings in the following description show only some embodiments of the present invention, and persons of ordinary skill in the art may still derive other drawings from these accompanying drawings without creative efforts.

FIG. 1 is a flowchart of a method for reducing dynamic power consumption according to an embodiment of the present invention;

FIG. 2 is a schematic connection diagram of a smart gating function circuit (Smart_gt) circuit in a method for reducing dynamic power consumption according to an embodiment of the present invention;

FIG. 3 is a schematic diagram of an application scenario of bus architecture based on AMBA2.0 AHB;

FIG. 4 is another schematic connection diagram of a Smart_gt circuit in a method for reducing dynamic power consumption according to an embodiment of the present invention;

FIG. 5 is still another schematic connection diagram of a Smart_gt circuit in a method for reducing dynamic power consumption according to an embodiment of the present invention;

FIG. 6 is still another schematic connection diagram of a Smart_gt circuit in a method for reducing dynamic power consumption according to an embodiment of the present invention;

FIG. 7 is a working sequence relation diagram of a Smart_gt circuit in a method for reducing dynamic power consumption according to an embodiment of the present invention; and

FIG. 8 is a schematic structural diagram of an electronic device according to an embodiment of the present invention.

### DESCRIPTION OF EMBODIMENTS

The following clearly describes the technical solutions in the embodiments of the present invention with reference to the accompanying drawings in the embodiments of the present invention. Apparently, the embodiments to be described are only a part rather than all of the embodiments of the present invention. All other embodiments obtained by persons of ordinary skill in the art based on the embodiments of the present invention without creative efforts shall fall within the protection scope of the present invention.

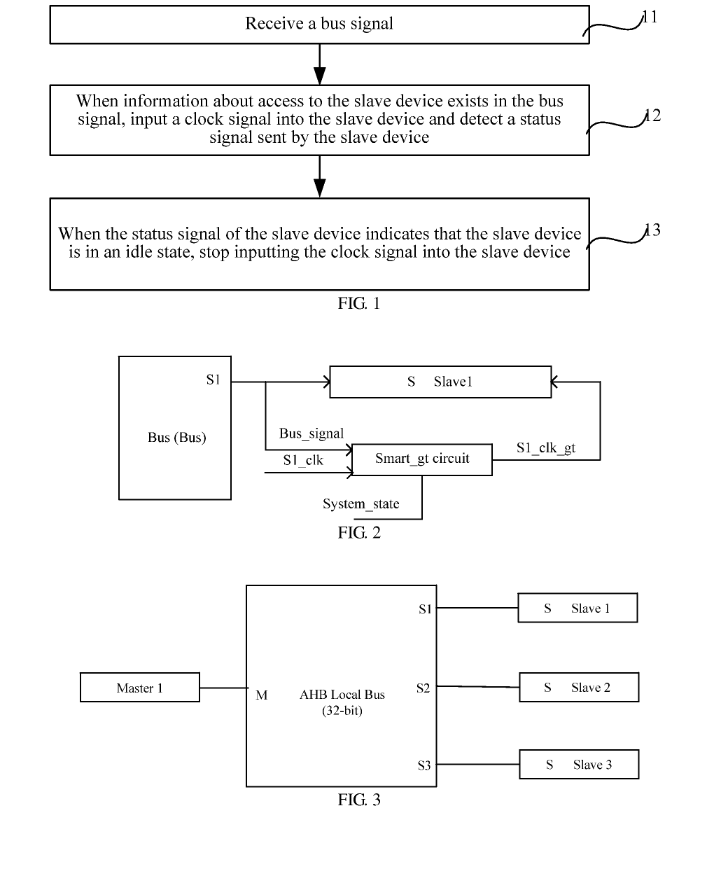

FIG. 1 is a flowchart of a method for reducing dynamic power consumption according to an embodiment of the present invention. As shown in FIG. 1, the method for reducing dynamic power consumption includes:

Step 11: Receive a Bus Signal.

The bus signal (Bus_signal) is a general designation of a combination of multiple bus signals and may include bus address (HADDR[31:0]) signal and bus transfer (HTRANS[1]) signal of an AMBA2.0 bus. States of HADDR[31:0] and HTRANS[1] signals are used to determine whether a master device that needs to access a slave device (Slave) exists in a system. If a master device that needs to access a slave device exists in the system, a clock signal is provided for the slave device.

An address of a slave device in the system is unique. Therefore, when a value of a bus address HADDR[31:0] is equal to an address of a certain slave device and HTRANS[1]=1′b1, it indicates that a master device that needs to access the slave device exists in the system. This method also applies to another bus. A determination that a bus address is equal to a slave device and that the bus access is a valid operation is used as a flag that indicates that a master device in the system is accessing the slave device. The flag is used as a condition for inputting a clock signal into the slave device.

Step 12: When information about access to the slave device exists in the bus signal, input a clock signal into the slave device and detect a status signal sent by the slave device.

A detecting module may detect whether the information about access to the slave device exists in the bus signal and detect the status signal sent by the slave device. The clock signal may be generated by a clock module and may also be a clock signal received by the clock module.

When the information about access to the slave device exists in the bus signal, it indicates that a condition for turning on the clock module is satisfied, and the clock module inputs a clock signal into the slave device. When the clock signal is a clock signal received by the clock module, the clock signal may be a clock signal provided for the slave device by another device that accesses the slave device in the prior art, and the clock keeps being turned on during system working.

The status signal, such as S1_state, sent by the slave device is a general designation of a combination of working status signals of a certain slave device, and the combined signal is provided by the slave device and may be one or more signals. In the present invention, whether a slave device has stopped working is determined by determining a status signal. For example, a status register S1_state[1:0] whose bit width is two bits is located in the slave device. When S1_state[1:0]=2′b00, it indicates that the slave device is in an idle state, also called a non-working state. The idle state is used as a condition for stopping providing a clock signal for the slave device. When S1_state[1:0]=2′b00, the clock module is turned off, and in this case, an output clock input into the slave device is a non-reversible fixed value.

The methods for indicating that each slave device stops working are different. Therefore, a status signal of each different slave device in a same system or a different system needs to be set separately and specifically according to a different slave device. For example, detecting the status signal sent by the slave device may include detecting an interface status signal sent by the slave device, or may include detecting a status signal of an internal circuit, where the status signal is sent by the slave device.

Step 13: When the status signal of the slave device indicates that the slave device is in an idle state, stop inputting the clock signal into the slave device. Whether the status signal of the slave device indicates that the slave device is in an idle state may be detected by the detecting module, an input clock signal may be provided by the clock module, and the clock module is turned off when a clock signal is stopped from being input into the slave device.

Herein, the detecting module and the clock module may be implemented by using one circuit. For ease of description, the circuit is called a smart gating function circuit, which is referred to as a Smart_gt circuit.

A Smart_gt internal gating clock circuit may be implemented by a logical combination of a clock signal, a bus signal (Bus_signal), a status signal of the slave device, and a gating clock signal that is input into the slave device, which specifically includes:

When a combined signal of the Bus_signal indicates that a bus needs to access a certain slave device, the gating clock signal is driven directly by the input clock signal. When a combined signal of the Bus_signal indicates that the bus does not need to access the slave device and a combined signal of the status signal of the slave device indicates that the slave device has stopped working, an output gating clock signal is 1′b0 or 1′b1, that is, a non-reversible fixed value.

Position setting of a Smart_gt circuit may depend on an implementation cost. For example, a Smart_gt circuit is added near the slave device module and the bus; that is, a position of the Smart_gt circuit may be between the slave device module and the bus, and the Smart_gt circuit may be located inside the slave device module and may also be located inside the bus.

In some systems, a working state of a slave device (Slave) cannot be acquired directly through an internal state of the Slave when the following situation occurs: an interface signal of a Slave module in a system cannot provide a working state of the Slave; a Slave module in a system is too complex to understand; a Slave module in a system is not authorized by a provider and cannot be modified; a Slave module in a system is a netlist or a file in another format, where the netlist or the file in another format cannot be read; or a Slave module in a system is a non-programmable chip or a programmable device.

In this case, a working state of a Slave may be generated by using a working state of the bus or a system level. As shown in FIG. 2, a Smart_gt circuit determines a working state of a Slave1 by using a Bus_signal and a system state (System_state) and then controls a working clock, specifically the gating clock signal of Slave1 (S1_clk_gt).

Many methods may be used to acquire the working state of the Slave. For example, after a start working state of the Slave may be acquired through a Bus_signal behavior, working end time of the Slave is determined according to working time of the Slave. For another example, a working state of the Slave may be acquired through a state of another module that is related to the Slave.

In this embodiment, a working clock of a device module, such as a slave device module, in a chip is controlled by detecting a status signal of the slave device and a bus signal, which prevents unnecessary circuit turnover from occurring to the device module in the chip in a non-working state, thereby achieving a purpose of reducing dynamic power consumption of the device module in the chip. Moreover, a manner of detecting the status signal of the slave device and the bus signal is used, which prevents an additional load from being brought to software running due to detection and configuration implemented by using software for entering a power consumption saving state in the prior art, and solves a problem that poor timeliness and a poor power consumption saving effect are caused by using of the software to control the entering of the power consumption saving state.

In the foregoing embodiment, both a master device module and a slave device module in bus architecture may use the same method to reduce their dynamic power consumption. Each device module has a corresponding detecting module to perform detection, and controls turning on/turning off a working clock of each device module according to a detection result. This is because Bus_signal behaviors, which correspond to various device modules, of starting working (S1_start) in the bus are different, and methods for indicating a working state, such as an idle state (S1_idle), corresponding to each device module in the bus are different.

According to the method for reducing power consumption provided in the foregoing embodiment, a Smart_gt circuit may also be set for only a device module that has relatively large power consumption in the bus to effectively reduce dynamic power consumption.

The foregoing embodiment may apply to the following scenarios: a scenario in which master and slave device modules are inside a same Application Specific Integrated Circuit (ASIC) chip (in this case, a bus category may be Advanced Peripheral Bus (APB) or Advanced System Bus (ASB) of AMBA2.0, Advanced eXtensible Interface (AXI), AHB, APB, or ASB of AMBA3.0, Wishbone, Avalon, Coreconnect, or an Open Core Protocol (OCP) bus); a scenario in which master and slave device modules are inside a same programmable logic device (such as an Field Programmable Gate Array (FPGA), a Complex Programmable Logic Device (CPLD), a Programmable Array Logic (PAL), a Generic Array Logic (GAL), or an Erasable Programmable Logic Device (EPLD); in this case, a bus category may be APB or ASB of AMBA2.0, AXI, AHB, APB, or ASB of AMBA3.0, Wishbone, Avalon, Coreconnect, or an OCP bus); a scenario in which a master device module is inside an ASIC chip and a slave device module is outside an ASIC chip (in this case, when the master and slave device modules interconnect through a certain bus or interface protocol, a Smart_gt circuit may be set in any chip and may also be implemented at an external circuit board level by using a programmable logic device (such as an FPGA, a CPLD, a PAL, a GAL, or an EPLD)); a scenario in which a master device module is inside a programmable logic device (such as an FPGA, a CPLD, a PAL, a GAL, or an EPLD) and a slave device module is inside an ASIC chip (in this case, when the master and slave device modules interconnect through a certain bus or interface protocol, a Smart_gt circuit may be set and implemented in a programmable logic device of any master device module, may also be implemented in the ASIC chip of the slave device module, and may also be implemented at an external circuit board level by using a programmable logic device (such as an FPGA, a CPLD, a PAL, a GAL, or an EPLD)); and a scenario in which a master device module is inside an ASIC chip and a slave device module is inside a programmable logic device (such as an FPGA, a CPLD, a PAL, a GAL, or an EPLD; in this case, when the master and slave device modules interconnect through a certain bus or interface protocol, a smart gating module may be set and implemented in an ASIC chip of any master device module, may also be implemented in the programmable logic device of the slave device module, and may also be implemented at an external circuit board level by using a programmable logic device (such as an FPGA, a CPLD, a PAL, a GAL, or an EPLD)).

The following uses bus architecture that is based on AMBA2.0 AHB and shown in FIG. 3 as an application scenario to describe the method for reducing dynamic power consumption in further detail.

As shown in FIG. 3, the bus architecture based on AMBA2.0 AHB is formed by three parts, that is, a bus (AHB Local Bus), a master device module (Masterl), and slave device modules (Slave1-Slave3). The master and slave device modules are devices, such as IP cores, chips, or circuit modules, and the Masterl and the Slave1-Slave3 are all connected to an AMBA bus. Whether working power consumption of the Masterl and the Slave 1-Slave3 can be saved depending on whether internal logic circuits of these modules can be stopped from working when these modules do not work, and a most direct method is to use a Smart_gt circuit to turn off working clocks of these device modules when these device modules do not work.

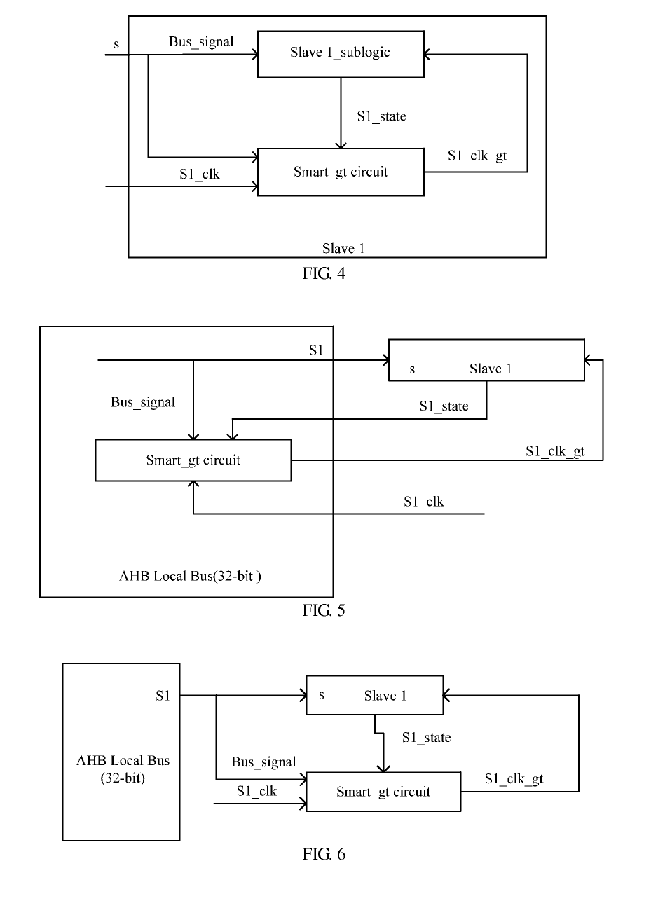

Reducing dynamic power consumption of the Slave1 is taken as an example. For setting of the Smart_gt circuit in the bus architecture based on AMBA2.0 AHB, the Smart_gt circuit may be located between the Slave1 and the bus, as shown in FIG. 4, may also be located in the Slave1, as shown in FIG. 5, and may also be located in the bus, as shown in FIG. 6.

Smart_gt circuit setting shown in FIG. 6 is taken as an example. A Smart_gt circuit is set outside the Slave1, the Smart_gt circuit and the Slave1 are connected to the bus, and an interface signal between them is described as follows:

Input signals of the Smart_gt circuit include a Bus_signal (bus signal), an S1_clk (working clock of the Slave1), and an S1_state (working state of the Slave1).

An output signal S1_clk_gt of the Smart_gt circuit is a working clock that is output to the Slave1 after the output signal passes through the Smart_gt circuit.

The Smart_gt circuit uses the Bus_signal to detect and determine whether the Slave1 starts working and uses the S1_state to detect and determine whether the Slave1 ends working.

When detecting that the Slave1 starts working, the Smart_gt circuit turns on the S1_clk_gt; and when detecting that the Slave1 ends working, the Smart_gt circuit turns off the S1_clk_gt.

The Smart_gt circuit turns on or turns off the working clock by accurately detecting a working requirement of the Slave1, which prevents unnecessary turnover from occurring to the Slave1 in an idle state, thereby effectively saving dynamic power consumption of the Slave1.

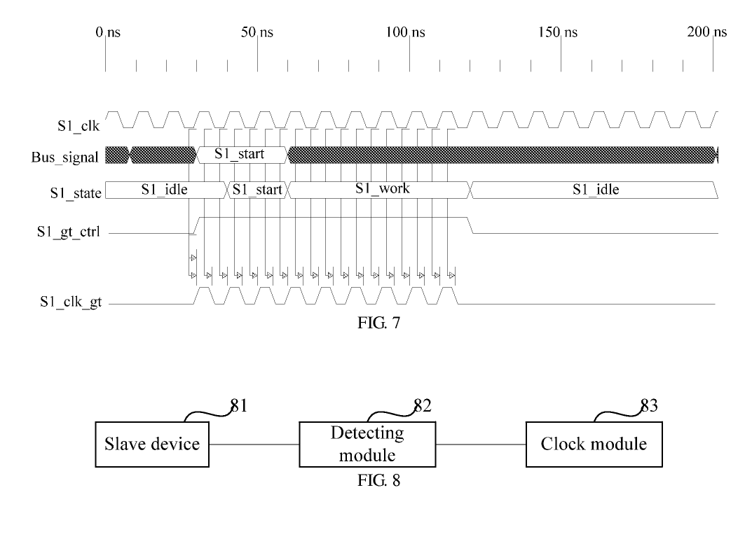

A working sequence relation of the Smart_gt circuit is shown in FIG. 7.

States of a status signal (S1_state) of the Slave1 include S1_idle (idle), S1_start (start), and S1_work (work). S1_idle indicates that the Slave1 is in an idle state, and in this case, the Slave1 does not need to work; and S1_start and S1_work indicate that the Slave1 is in a working state. The S1_state may be generated by the Smart_gt circuit by detecting an interface signal state of the Slave1 module and may also be generated by detecting a status signal of an internal circuit of the Slave1 module, as long as the working state of the Slave1 can be reflected correctly.

The Smart_gt circuit detects a bus behavior by using the Bus_signal. When S1_start is obtained through detection, it indicates the state that the Slave1 starts working. The S1_start is obtained by the Smart_gt circuit by parsing the Bus_signal. For example, in a system, if the Slave1 needs to work, the system must configure a register of the Slave1 by using a bus to start the work of the Slave1. In this case, as long as a behavior that the bus accesses the register of the Slave1 is detected by using the Bus_signal, it is considered that the system requires the Slave1 to enter a working state. In this case, the Smart_gt considers that the Slave1 needs to work and must turn on a working clock S1_clk_gt for the Slave1.

After the Smart_gt circuit turns on the working clock for the Slave1, the Smart_gt circuit starts detecting a working state S1_state of the Slave1. The working state of the Slave1 is acquired by the Smart_gt circuit by analyzing a feature of an internal working circuit of the Slave1. For example, the internal working circuit of the Slave1 generally has a logic state machine. If the state machine is in an IDLE state, it indicates a non-working state; and if the state machine is in another state, it indicates a working state. Manners for indicating working states of different device modules are different. For example, internal logic implementation methods of two IP cores, such as an Inter-Integrated Circuit (I2C) and a Serial Peripheral Interface (SPI), are different, and therefore logic signals for indicating their working states are also different. When it is detected that S1_state is S1_idle, it indicates that the Slave1 has completed work and enters an idle state. In this case, the Smart_gt circuit turns off a gating clock S1_clk_gt and stops providing a working clock for the Slave1.

It can also be seen from FIG. 7 that the Smart_gt circuit detects the working state of the Slave1 and the bus behavior to accurately control the working clock of the Slave1, thereby avoiding unnecessary circuit turnover of the Slave1 to the maximum extent and achieving a purpose of saving dynamic power consumption of the Slave1.

Persons of ordinary skill in the art may understand that all or a part of the steps in the method embodiments may be implemented by a program instructing relevant hardware. The program may be stored in a computer readable storage medium. When the program is run, the steps in the method embodiments are performed. The storage medium may be any medium that is capable of storing program codes, such as a read only memory (ROM), a random access memory (RAM), a magnetic disk, or an optical disk.

FIG. 8 is a schematic structural diagram of an electronic device according to an embodiment of the present invention. As shown in FIG. 8, the electronic device is configured to implement the method in the foregoing embodiment shown in FIG. 1, and includes a slave device 81, a detecting module 82, and a clock module 83. For details about the slave device 81, the detecting module 82, and the clock module 83, reference is made to the description in the foregoing method embodiments.

The slave device 81 is configured to receive and process, through a bus, access information sent by another device. The detecting module 82 is configured to detect a status signal of the slave device 81 and a bus signal. For example, the detecting module 82 is specifically configured to detect an interface status signal sent by the slave device 81 or is specifically configured to detect a status signal of an internal circuit, where the status signal is sent by the slave device 81.

The clock module 83 is configured to input a clock signal into the slave device 81 when the detecting module 82 detects that information about access to the slave device 81 exists in the bus signal, and stop inputting the clock signal into the slave device 81 when the detecting module 82 detects that the status signal of the slave device 81 indicates that the slave device 81 is in an idle state.

Optionally, the clock module 83 is further configured to receive a clock signal, and the clock module is specifically configured to input the received clock signal into the slave device when the detecting module detects that the information about access to the slave device exists in the bus signal.

In the foregoing device embodiment, a detecting module and a clock module are added into an electronic device in bus architecture to implement control over a working clock of a master device module or a slave device module, and a Smart_gt circuit may control, by detecting a working state of a device module whose dynamic power consumption is to be reduced and a bus state, turning on/turning off of a working clock input by a system into the device module whose dynamic power consumption is to be reduced, to reduce dynamic power consumption of the master device module or the slave device module.

According to the foregoing method and system embodiments, no software is required for detection and configuration, and therefore a software overhead does not increase, which avoids a problem that using software to implement detection and configuration for entering a power consumption saving state generally brings an additional load to software running and a problem that the more accurate software control required for saving more power consumption is, the larger a software overhead is. Moreover, no matter whether a device module in a chip has a function of saving dynamic power consumption, on which no restriction or dependence is imposed, working power consumption of a device module in a chip may be reduced. Real-time monitoring can be implemented, control precision is high, and an effect of saving power consumption is obviously better than a traditional method for saving power consumption through software control. Specific gains for saving power consumption depend on a busy degree of a device module in a chip in an actual system. For example, in a certain period, the device module in the chip in the actual system actually works for 20% of the time and is idle for 80% of the time. In the present invention, it may be ensured that a working clock of the device module in the chip is turned off in 80% of the time when the device module in the chip is in an idle state, which saves 100% of dynamic power consumption of the device module in the chip in the idle state, thereby saving all logic power consumption of the device module in the chip.

Finally, it should be noted that the foregoing embodiments are only intended for describing the technical solutions of the present invention rather than limiting the present invention. Although the present invention is described in detail with reference to the foregoing embodiments, persons of ordinary skill in the art should understand that they may still make modifications to the technical solutions described in the foregoing embodiments or make equivalent replacements to some technical features of the technical solutions; however, these modifications or replacements do not make the essence of corresponding technical solutions depart from the spirit and scope of the technical solutions in the embodiments of the present invention.

What is claimed is:

1. A method for reducing dynamic power consumption of a slave device, the method comprising:
receiving a bus signal;
inputting a clock signal into the slave device when information about access to the slave device exists in the bus signal;
detecting a status signal sent by the slave device when information about access to the slave device exists in the bus signal; and
stopping input of the clock signal into the slave device when the status signal of the slave device indicates that the slave device is in an idle state.

2. The method for reducing dynamic power consumption according to claim 1, wherein detecting the status signal sent by the slave device comprises detecting an interface status signal sent by the slave device.

3. The method for reducing dynamic power consumption according to claim 1, wherein detecting the status signal sent by the slave device comprises detecting a status signal of an internal circuit, and wherein the status signal is sent by the slave device.

4. The method for reducing dynamic power consumption according to claim 1, further comprising receiving a clock signal, wherein inputting the clock signal into the slave device comprises inputting the received clock signal into the slave device through a clock circuit.

5. An electronic device comprising:
a slave device configured to receive and process, through a bus, access information sent by another device, wherein the electronic device comprises:
a detecting module configured to detect a status signal of the slave device and a bus signal; and
a clock module configured to:
input a clock signal into the slave device when the detecting module detects that information about access to the slave device exists in the bus signal; and
stop input of the clock signal into the slave device when the detecting module detects that the status signal of the slave device indicates that the slave device is in an idle state.

6. The electronic device according to claim 5, wherein the detecting module is configured to detect an interface status signal sent by the slave device.

7. The electronic device according to claim 5, wherein the detecting module is configured to detect a status signal of an internal circuit, and wherein the status signal is sent by the slave device.

8. The electronic device according to claim 5, wherein the clock module is further configured to:
receive a clock signal; and
input the received clock signal into the slave device when the detecting module detects that the information about access to the slave device exists in the bus signal.

9. A computer program product comprising instructions stored on a non-transitory storage medium, wherein the instructions cause a processor to reduce dynamic power consumption of a slave device by:
receiving a bus signal;
inputting a clock signal into the slave device when information about access to the slave device exists in the bus signal;
detecting a status signal sent by the slave device when information about access to the slave device exists in the bus signal; and
stopping input of the clock signal into the slave device when the status signal of the slave device indicates that the slave device is in an idle state.

10. The computer program product of claim 9, wherein detecting the status signal sent by the slave device comprises detecting an interface status signal sent by the slave device.

11. The computer program product of claim 9, wherein detecting the status signal sent by the slave device comprises detecting a status signal of an internal circuit, and wherein the status signal is sent by the slave device.

12. The computer program product of claim 9, further comprising receiving a clock signal, wherein inputting the clock signal into the slave device comprises inputting the received clock signal into the slave device through a clock circuit.
